(19) United States
(12) Patent Application Publication
(10) Pub. No.: US 2013/0270515 A1
(43) Pub. Date: Oct. 17, 2013

(54) LIGHT EMITTING DIODE

(71) Applicant: Yi-Keng Fu, Hsinchu County (TW)

(72) Inventor: Yi-Keng Fu, Hsinchu County (TW)

(73) Assignee: INDUSTRIAL TECHNOLOGY RESEARCH INSTITUTE, Hsinchu (TW)

(21) Appl. No.: 13/481,966

(22) Filed: May 29, 2012

(30) Foreign Application Priority Data
Apr. 12, 2012 (TW) 101113026

(51) Int. Cl. H01L 33/04

(52) U.S. Cl. 257/13; 257/E33.008

(57) ABSTRACT

A light emitting diode includes a substrate, an n-type semiconductor layer, a p-type semiconductor layer, an active layer, a first electrode, and a second electrode. The n-type semiconductor layer is located between the substrate and the p-type semiconductor layer. The active layer is located between the n-type semiconductor layer and the p-type semiconductor layer. The wavelength of light emitted by the active layer is λ, and 222 nm≦λ≦405 nm. The active layer includes i quantum barrier layers and (i−1) quantum wells, each quantum well is located between any two quantum barrier layers, and i is an integer greater than or equal to 2. The thickness of each of the quantum barrier layers counting from the p-type semiconductor layer is T₁ to Tᵢ, and T₁ is greater than T₂ and T₃, or T₁=T₂>T₃, or T₁>T₂>T₃.

### CROSS-REFERENCE TO RELATED APPLICATION

This application claims the priority benefit of Taiwan application serial no. 101113026, filed on Apr. 12, 2012. The entirety of the above-mentioned patent application is hereby incorporated by reference herein and made a part of this specification.

### BACKGROUND

1. Technical Field

The disclosure relates to a light emitting diode (LED), and more particularly, to an LED capable of enhancing luminous intensity.

2. Related Art

A light emitting diode (LED) is a semiconductor device constituted mainly by group III-V compound semiconductor materials, for instance. Such semiconductor materials have a characteristic of converting electricity into light; hence, when a current is applied to the semiconductor materials, electrons therein would be combined with holes and release excessive energy in a form of light, thereby achieving an effect of luminosity.

For instance, it is assumed that the LED is made of a nitride-based semiconductor material. Since the nitride-based semiconductor has direct bandgap (Eg) from the deep ultraviolet (UV) waveband to the far-infrared waveband (6.2 eV to 0.7 eV), the nitride-based material is not only promising for fabricating the LED with wavelengths ranging from green to ultraviolet but also characterized by high internal quantum efficiency (IQE). However, the polarization phenomenon exists in the nitride-based material may bring about band bending effects on an active layer, and electron-hole pairs are not overlap in quantum wells. Therefore, radiative recombination of the electron-hole pairs cannot be effectively accomplished. From another perspective, electrons easily overflows to the p-type semiconductor layer and results in reduction of luminous intensity. Besides, since hole mobility is less than electron mobility, therefore, when holes are injected into the active layer from the p-type semiconductor layer, the holes are mostly confined in the quantum well closest to the p-type semiconductor layer and cannot be evenly distributed into all quantum wells. This also leads to reduction of luminous intensity. As a result, manufacturers in the pertinent art endeavor to develop LED with satisfactory luminous intensity.

### SUMMARY

In an exemplary embodiment, an LED is provided. In the LED, one of the three quantum barrier layers closest to a p-type semiconductor layer has a thickness greater than thicknesses of the other two quantum barrier layers. Thereby, electron-hole pairs may be evenly distributed into the quantum barrier layers of the active layer, and luminous intensity of the LED at the 222 nm-405 nm wavelength range can be improved.

In an exemplary embodiment, another LED is provided. In the LED, thicknesses of three quantum barrier layers closest to a p-type semiconductor layer satisfy a certain relationship, such that electron-hole pairs may be evenly distributed into the quantum barrier layers of the active layer, and that luminous intensity of the LED at the 222 nm-405 nm wavelength range can be improved.

According to an exemplary embodiment of the disclosure, an LED that includes a substrate, an n-type semiconductor layer, a p-type semiconductor layer, an active layer, a first electrode, and a second electrode is provided. The n-type semiconductor layer is located between the substrate and the p-type semiconductor layer. The active layer is located between the n-type semiconductor layer and the p-type semiconductor layer. A wavelength of light emitted by the active layer is λ, and 222 nm≦λ≦405 nm. The active layer includes i quantum barrier layers and (i−1) quantum wells, each of the quantum wells is located between any two of the quantum barrier layers, and i is an integer greater than or equal to 2. A thickness of each of the quantum barrier layers, counting from the p-type semiconductor layer, is T₁, T₂, T₃ . . . , and Tᵢ in sequence, and T₁ is greater than T₂ and T₃. The first electrode is located on a portion of the n-type semiconductor layer, and the second electrode is located on a portion of the p-type semiconductor layer.

According to another exemplary embodiment of the disclosure, an LED that includes a substrate, an n-type semiconductor layer, a p-type semiconductor layer, an active layer, a first electrode, and a second electrode is provided. The n-type semiconductor layer is located between the substrate and the p-type semiconductor layer. The active layer is located between the n-type semiconductor layer and the p-type semiconductor layer. A wavelength of light emitted by the active layer is λ, and 222 nm≦λ≦405 nm. The active layer includes i quantum barrier layers and (i−1) quantum wells, each of the quantum wells is located between any two of the quantum barrier layers, and i is an integer greater than or equal to 2. A thickness of each of the quantum barrier layers, counting from the p-type semiconductor layer, is T₁, T₂, T₃ . . . , and Tᵢ in sequence, and T₁=T₂>T₃. The first electrode and the second electrode are respectively located on a portion of the n-type semiconductor layer and on a portion of the second semiconductor layer.

To recapitulate, in the LED described in the embodiments of the disclosure, one of the three quantum barrier layers closest to the p-type semiconductor layer has a thickness greater than thicknesses of the other two quantum barrier layers, or the thickness of the quantum barrier layer in the active layer satisfy a certain relationship. Thereby, electron-hole pairs may be evenly distributed into the active layer, the probability of electro-hole recombination may be increased, and luminous intensity of the LED at the 222 nm-405 nm wavelength range can be significantly improved.

Several exemplary embodiments accompanied with figures are described in detail below to further describe the disclosure in details.

### BRIEF DESCRIPTION OF DRAWINGS

The accompanying drawings are included to provide further understanding, and are incorporated in and constitute a part of this specification. The drawings illustrate exemplary embodiments and, together with the description, serve to explain the principles of the disclosure.

FIG. 1 is a schematic cross-sectional diagram illustrating an LED according to an exemplary embodiment.

FIG. 2A is a schematic cross-sectional diagram illustrating an active layer having a single quantum well structure in an LED according to an exemplary embodiment.

FIG. 2B is a schematic cross-sectional diagram illustrating an active layer having a multi-quantum well structure in an LED according to an exemplary embodiment.

FIG. 3 is an enlarged schematic cross-sectional diagram illustrating an active layer in an LED according to an exemplary embodiment.

FIG. 4A to FIG. 4C are structural diagrams illustrating design of several LEDs according to an exemplary embodiment.

FIG. 5 is a simulation diagram illustrating luminous intensity of the LEDs respectively depicted in FIG. 4A to FIG. 4C.

FIG. 6A to FIG. 6C are simulation diagrams illustrating electron and hole concentrations of the LEDs respectively depicted in FIG. 4A to FIG. 4C.

FIG. 7A and FIG. 7B are simulation diagrams illustrating energy bands of the LEDs respectively depicted in FIG. 4B and FIG. 4C.

FIG. 8 is a simulation diagram illustrating electron current density of the LEDs respectively depicted in FIG. 4A to FIG. 4C.

FIG. 9 illustrates light output power-injection current curves of the LEDs provided in Table 2.

### DETAILED DESCRIPTION OF DISCLOSED EMBODIMENTS

Below, exemplary embodiments will be described in detail with reference to accompanying drawings so as to be easily realized by a person having ordinary knowledge in the art. The inventive concept may be embodied in various forms without being limited to the exemplary embodiments set forth herein. Descriptions of well-known parts are omitted for clarity, and like reference numerals refer to like elements throughout.

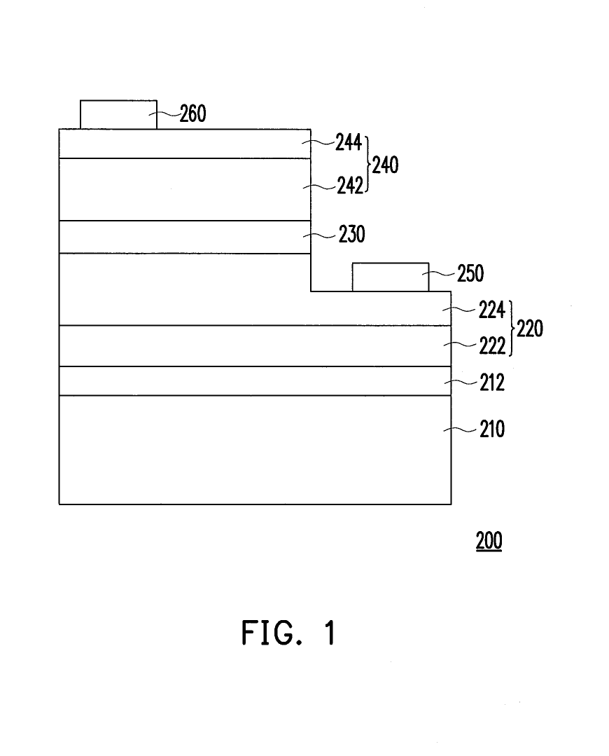

FIG. 1 is a schematic cross-sectional diagram illustrating an LED according to an exemplary embodiment.

With reference to FIG. 1, an LED 200 includes a substrate 210, an n-type semiconductor layer 220, an active layer 230, a p-type semiconductor layer 240, a first electrode 250, and a second electrode 260. The substrate 210 is, for instance, a sapphire substrate. Specifically, the stacking layers of a nitride semiconductor capping layer 212 (e.g. un-doped GaN), a n-type semiconductor layer 220, an active layer 230, the active layer 230 and the p-type semiconductor layer 240 are formed in sequence on a surface of the sapphire substrate 210. The active layer 230 is disposed between the n-type semiconductor layer 220 and the p-type semiconductor layer 240. The n-type semiconductor layer 220 may include the stacking layers of a first n-type doped GaN layer 222 and a second n-type doped GaN layer 224 disposed sequentially on the nitride semiconductor capping layer 212. The p-type semiconductor layer 240 may include the stacking layers of a first p-type doped GaN layer 242 and a second p-type doped GaN layer 244 disposed sequentially on the active layer 230. A difference between the first n-type doped GaN layer 222 and the second n-type doped GaN layer 224, or a difference between the first p-type doped GaN layer 242 and the second p-type doped GaN layer 244 may be in thickness or in doping concentration. Besides, a material of the n-type semiconductor layer 220 and the p-type semiconductor layer 240 may be AlGaN, for instance. According to requirements in practice, people skilled in the art may select the thickness, the doping concentration, and the aluminum concentration for growth of the nitride semiconductor capping layer 212, the first n/p-type doped GaN layers 222 and 242, the second n/p-type doped GaN layers 224 and 244, although the disclosure is not limited thereto.

Specifically, as shown in FIG. 1, the nitride semiconductor capping layer 212 (e.g. un-doped GaN), the first n-type doped GaN layer 222 and the second n-type doped GaN layer 224, the active layer 230, the first p-type doped GaN layer 242, and the second p-type doped GaN layer 244 are formed in sequence on the sapphire substrate 210. Moreover, the first electrode 250 and the second electrode 260 are respectively formed on a portion of the second n-type doped GaN layer 224 and the second p-type doped GaN layer 244, such that the first electrode 250 is electrically connected to the n-type semiconductor layer 220, and the second electrode 260 is electrically connected to the p-type semiconductor layer 240. Certainly, a nitride buffer layer may also be added between the sapphire substrate and the n-type semiconductor, although the disclosure is not limited thereto.

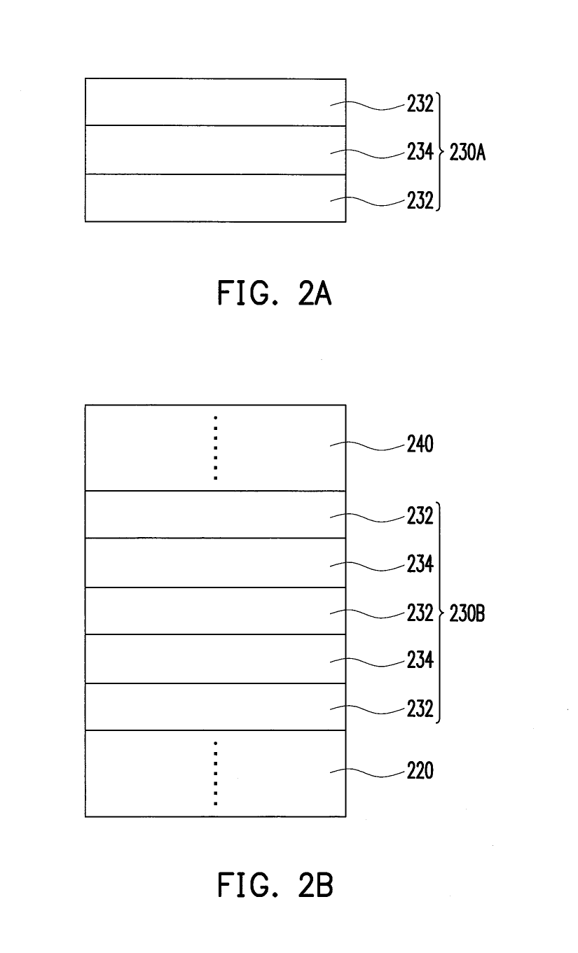

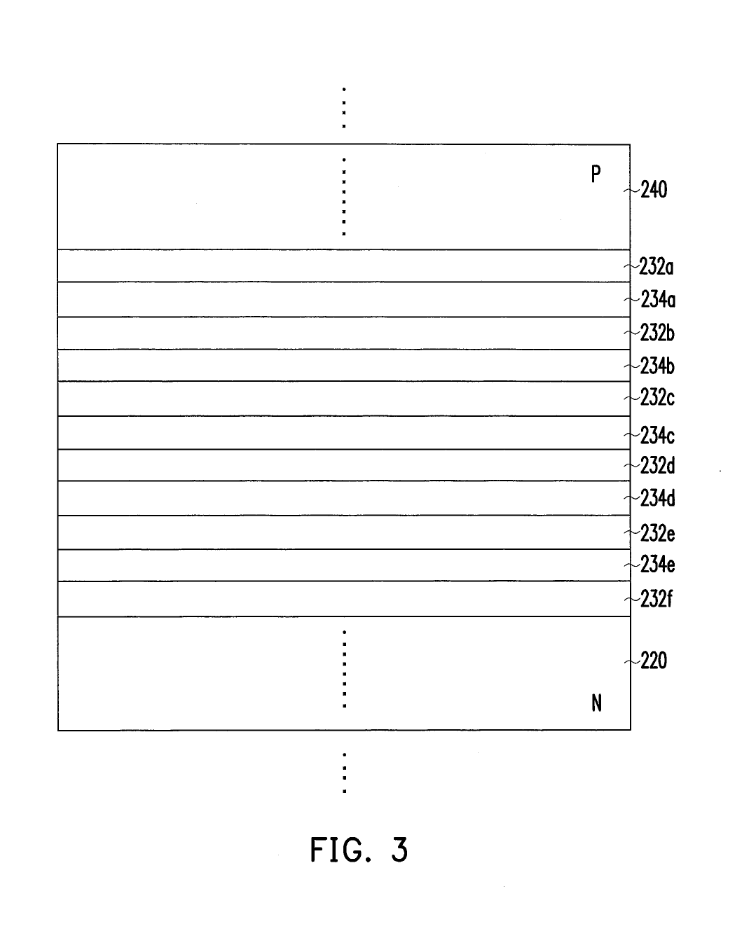

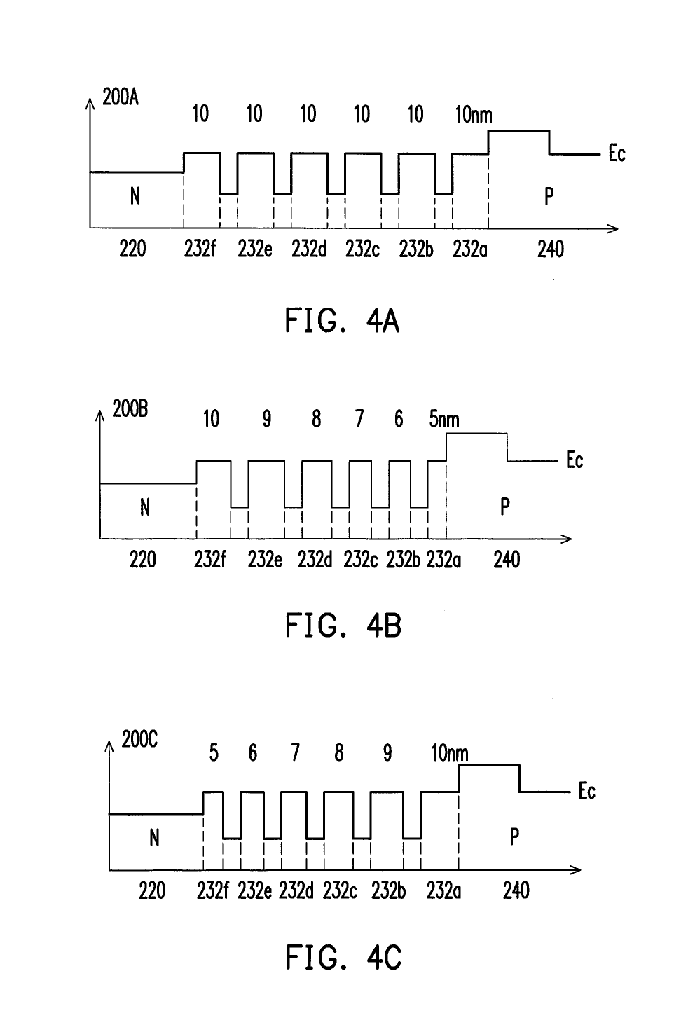

The active layer 230, as shown in FIG. 2A and FIG. 2B, may be composed of a single quantum well (i.e., a single quantum well active layer 230A) or multiple quantum wells (i.e., a multi-quantum well active layer 230B). FIG. 2A is a schematic cross-sectional diagram illustrating a single quantum well active layer in an LED according to an exemplary embodiment. FIG. 2B is a schematic cross-sectional diagram illustrating a multi-quantum well active layer in an LED according to an exemplary embodiment. In general, the active layer 230 includes i quantum barrier layers and (i−1) quantum wells. Each of the quantum wells is located between any two quantum barrier layers, and i is a natural number greater than or equal to 2. For instance, as shown in FIG. 2A, the single quantum well active layer 230A may be formed by two quantum barrier layers 232 and a quantum well 234 sandwiched therebetween, thus constituting a quantum barrier layer 232/quantum well 234/quantum barrier layer 232 structure. Taking the LED 200 with an emitted wavelength of 222 nm-405 nm as an example, a material of the quantum barrier layers 232 is AlₓIn_{y}Ga_{1-x-y}N, wherein 0≦x≦1, 0≦y≦0.3, and x+y≦1. Moreover, a material of the quantum well 234 may be AlₘInₙGa₁₋ₘ₋ₙN, wherein 0≦m≦1, 0≦n≦0.5, m+n≦1, x>m, and n≧y. According to requirements in practice, such as different emitted wavelengths, people skilled in the art may select the concentrations of m and n or x and y for growth, although the disclosure is not limited thereto. Besides, among the i quantum barrier layers 232, the quantum barrier layer 232a (shown in FIG. 3) that is closest to the p-type semiconductor layer 240 has the thickness T₁ ranging from about 6 nm to about 15 nm, for instance.

On the other hand, the active layer 230, as shown in FIG. 2B, may be composed of multiple quantum wells (i.e., the multi-quantum well active layer 230B). The multi-quantum well active layer 230B may be formed by at least two pairs of stacked quantum barrier layers 232 and quantum wells 234. For instance, in FIG. 2B, the multi-quantum well active layer 230B is composed of three pairs of stacked quantum barrier layers 232/quantum wells 234.

It should be mentioned that, in the active layer of the LED 200 of the disclosure, the quantum barrier layers 232 at different locations may be designed to have different thicknesses. To wit, the location of the active layer relative to the p-type semiconductor layer 240 determines the relative thickness of the quantum barrier layer 232, such that holes with low mobility may be easily moved toward the n-type semiconductor layer 220, and a favorable quantum confinement effect may be rendered on the adjacent quantum barrier layers. Thereby, the electron-hole pairs can be evenly distributed into the multiple quantum wells 234 of the active layer 230, and luminous intensity of the LED 200 at the 222 nm-405 nm wavelength range can be improved.

Through adjustment of the thickness of each quantum barrier layer 232 of the active layer 230, the electron-hole pairs can be evenly distributed into all quantum wells 234, and accordingly the luminous intensity can be effectively enhanced. In particular, holes are allowed to move toward the n-type semiconductor layer 220, and this may further enhance the light emitted by the active layer 230 at the 222 nm-405 nm wavelength range.

The enhancement of luminous intensity of the LED by way of adjustment of thickness of each quantum barrier layer in the active layer, as described in the disclosure, will be further described with support from the experimental results provided below. In the embodiments hereafter, the active layer 230 exemplarily has six quantum barrier layers 232, while people skilled in the art may actively change the layer number of the quantum barrier layers 232 in the active layer 230 (as shown in Table 3 below) and can still implement the embodiments.

FIG. 3 is an enlarged schematic cross-sectional diagram illustrating an active layer in an LED according to an exemplary embodiment. With reference to FIG. 3, the active layer 230 described in the present embodiment includes six quantum barrier layers 232a-232f and five quantum wells 234a-234e. Each of the quantum wells 234a-234e is located between any two of the quantum barrier layers 232a-232f. The quantum barrier layers 232a-232f, counting from the p-type semiconductor layer 240, are sequentially 232a, 232b, 232c, 232d, 232e, and 232f, and the quantum wells 234a-234e, counting from the p-type semiconductor layer 240, are sequentially 234a, 234b, 234c, 234d, and 234e.

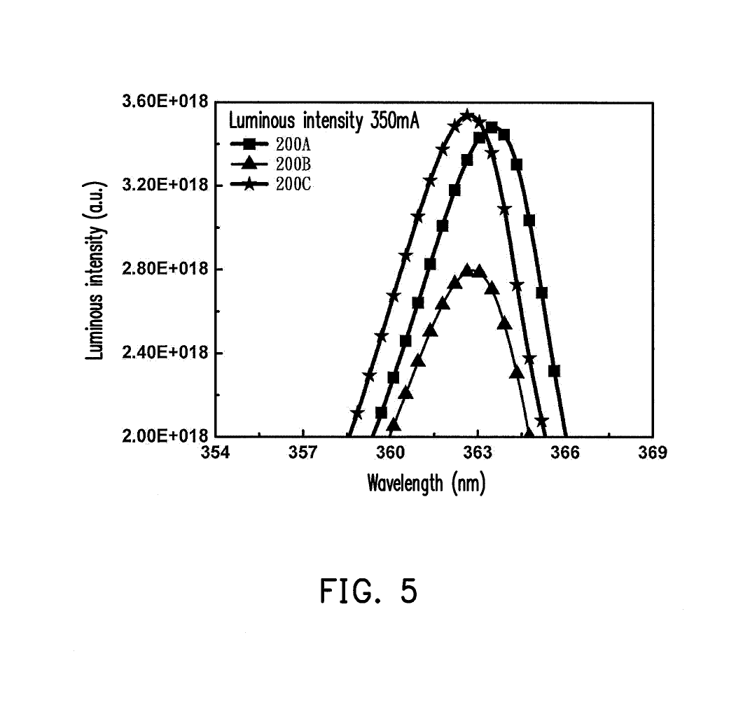

FIG. 4A to FIG. 4C are structural diagrams illustrating design of several LEDs according to an exemplary embodiment. The horizontal axis represents the location of the stacked quantum barrier layers in the LED, and the vertical axis represents the relative conductive band energy level. The thickness (unit: nm) of each quantum barrier layer is labeled above the quantum barrier layer.

In the LED 200A shown in FIG. 4A, the thicknesses of the quantum barrier layers 232a-232f remain unchanged; in the LED 200B shown in FIG. 4B, the thicknesses of the quantum barrier layers 232a-232f gradually increase if counting from the p-type semiconductor layer 240 to the n-type semiconductor layer 220; in the LED 200C shown in FIG. 4C, the thicknesses of the quantum barrier layers 232a-232f gradually decrease if counting from the p-type semiconductor layer 240 to the n-type semiconductor layer 220.

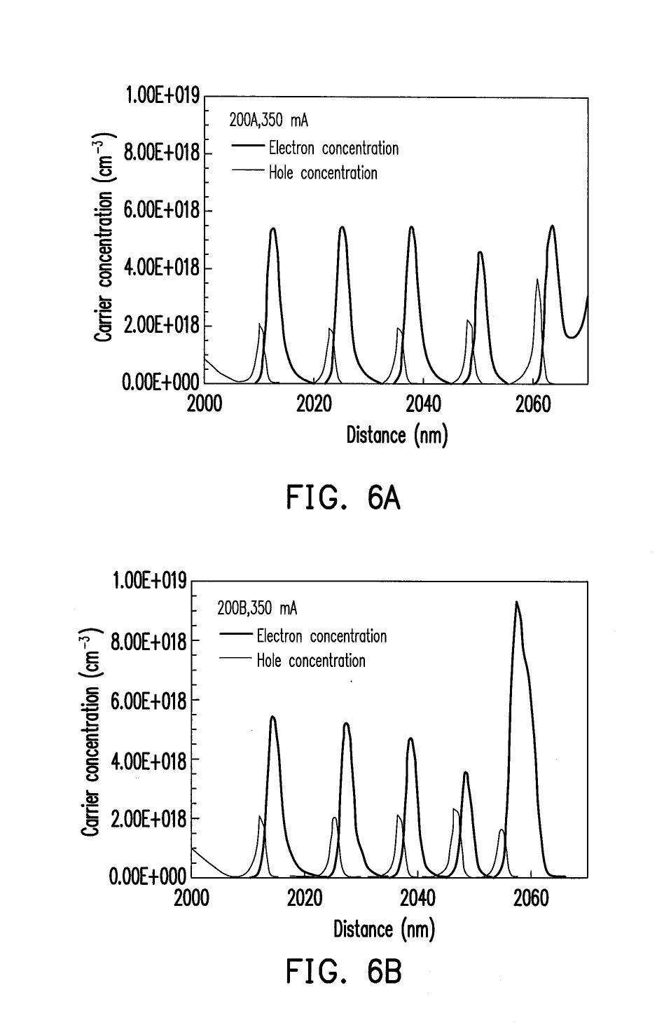

FIG. 5 is a simulation diagram illustrating luminous intensity of the LEDs respectively depicted in FIG. 4A to FIG. 4C. With reference to FIG. 5, the luminous intensity of the LED 200C (in which the thicknesses of the quantum barrier layers 232a-232f gradually decrease if counting from the p-type semiconductor layer 240 to the n-type semiconductor layer 220) is greater than both the luminous intensity of the LED 200A (in which the thicknesses of the quantum barrier layers 232a-232f remain unchanged) and the luminous intensity of the LED 200B (in which the thicknesses of the quantum barrier layers 232a-232f gradually increase if counting from the p-type semiconductor layer 240 to the n-type semiconductor layer 220). Note that the luminous intensity of the LED 200B (in which the thicknesses of the quantum barrier layers 232a-232f gradually increase if counting from the p-type semiconductor layer 240 to the n-type semiconductor layer 220) has the least value in comparison with the luminous intensity of the LEDs 200A and 200C.

The impact on the luminous intensity results from the difference in thicknesses of the quantum barrier layers in the LEDs 200A-200C, which is further explained below.

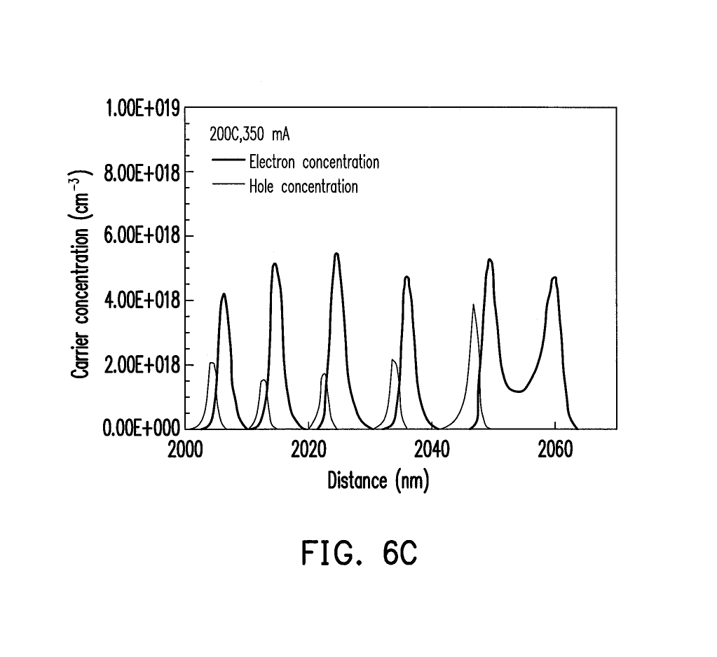

FIG. 6A to FIG. 6C are simulation diagrams illustrating electron and hole concentrations of the LEDs respectively depicted in FIG. 4A to FIG. 4C. The horizontal axis represents the distance (unit: nm) from the stacked layers to the substrate. A distance of 2060 nm is close to the p-type semiconductor layer 240, and a distance of 2000 is close to the n-type semiconductor layer 220. The thick line and the thin line respectively denote electron concentration and hole concentration (unit: cm⁻³).

The impact on the luminous intensity resulting from the difference in thicknesses of the quantum barrier layers in the LEDs may be derived from the results shown in FIG. 4A to FIG. 4C, FIG. 5, and FIG. 6A to FIG. 6C.

With reference to FIG. 4B and FIG. 6B, as to the electron mobility of the LED 200B, when the thicknesses of the quantum barrier layers 232a-232f gradually increase (if counting from the p-type semiconductor layer 240 to the n-type semiconductor layer 220), the electrons are injected into the n-type semiconductor layer 220, pass the quantum barrier layers 232a-232f, and are moved toward the p-type semiconductor layer 240. Therefore, when the thicknesses of the quantum barrier layers 232a-232f gradually decrease (if counting from the n-type semiconductor layer 220 to the p-type semiconductor layer 240), the electrons can be easily moved toward the p-type semiconductor layer 240. Thereby, the quantum well 234a closest to the p-type semiconductor layer 240 may have excessively high electron concentration.

With reference to FIG. 6B and FIG. 4B, as to the hole mobility of the LED 200B, the thickness of the quantum barrier layer 232a closest to the p-type semiconductor layer 240 is relatively small, and holes are more likely to move toward the n-type semiconductor layer 220. However, as described above, the quantum well 234a closest to the p-type semiconductor layer 240 has an excessive number of electrons, such that the electrons may not be recombined in the quantum well 234a but may overflow. Thereby, radiative recombination of electrons and holes cannot be effectively accomplished, the overall concentration of the injected holes is reduced, and the luminous intensity is lessened.

With reference to FIG. 4C and FIG. 6C, as to the electron mobility of the LED 200C, when the thicknesses of the quantum barrier layers 232a-232f gradually increase (if counting from the n-type semiconductor layer 220 to the p-type semiconductor layer 240), the electrons are injected toward the p-type semiconductor layer 240 from the n-type semiconductor layer 220 through the quantum barrier layers 232a-232f. The increasing thicknesses of the quantum barrier layers 232 slightly slow down the movement of electrons toward the p-type semiconductor layer 240. Hence, the electron concentration of each of the quantum wells 234a-234e in the active layer 230 can be uniform. Besides, since the thicknesses of the quantum barrier layers 232a-232f in the LED 200C gradually increase (if counting from the n-type semiconductor layer 220 to the p-type semiconductor layer 240), the electrons in the LED 200C, unlike the electrons in the LED 200B, are precluded from being concentrated in the quantum well 234a closest to the p-type semiconductor layer 240. As such, the overall concentration of injected electrons will not be negatively affected because the problem of electron overflow of the quantum well 234a does not occur.

As to the hole mobility of the LED 200C, with reference to FIG. 6C and FIG. 4C, when the holes are injected from the p-type semiconductor layer 240 to one of the quantum wells 234 (i.e., the quantum well 234a shown in FIG. 4C) which is closest to the p-type semiconductor layer 240, the holes may be easily injected to the quantum wells 234a-234e due to the decreasing thicknesses of the quantum barrier layers 232a-232f counting from the p-type semiconductor layer 240 to the n-type semiconductor layer 220. Thereby, the hole concentration of the quantum wells 234 in the LED 200C is relatively uniform in comparison with the hole concentration in the LEDs 200A and 200B, and thus the luminous intensity of the LED 200C is greater than the luminous intensity of the LED 200A and the LED 200B.

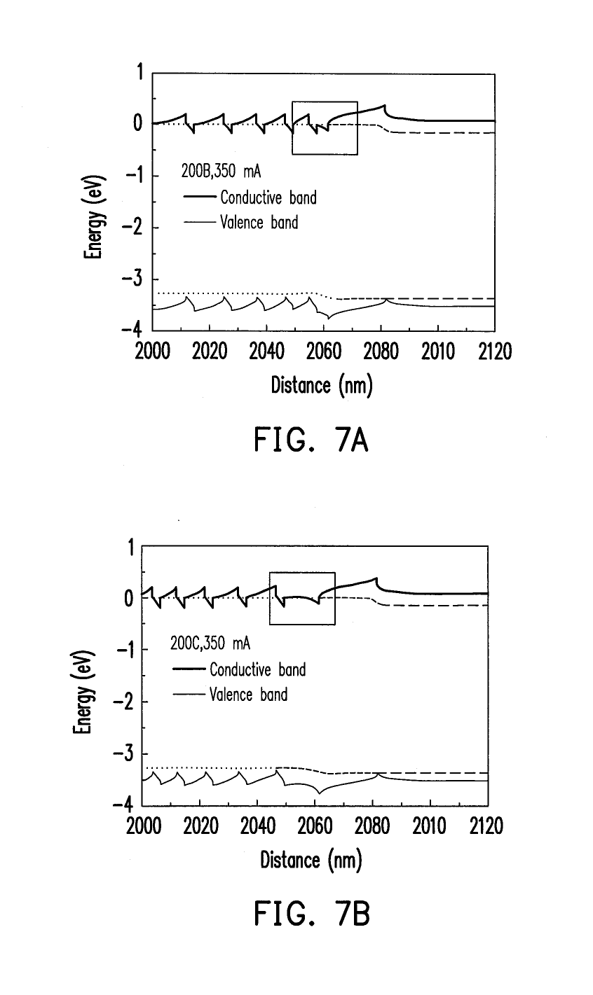

FIG. 7A and FIG. 7B are simulation diagrams illustrating energy bands of the LEDs respectively depicted in FIG. 4B and FIG. 4C. The definition of the horizontal axis in FIG. 7A and FIG. 7B is the same as that in FIG. 6A to FIG. 6C. With reference to FIG. 7A and FIG. 4B, when the thickness of the quantum barrier layer 232a closest to the p-type semiconductor layer 240 is reduced, the conductive band of the quantum barrier layer 232a is lower than the Fermi energy level (represented by dotted lines). Thereby, the quantum well 234a closest to the p-type semiconductor layer 240 does not exhibit quantum confinement properties, and electrons may overflow to the p-type semiconductor layer 240.

On the other hand, with reference to FIG. 7B and FIG. 4C, the thickness of the quantum barrier layer 232a closest to the p-type semiconductor layer 240 is relatively large, and thus the conductive band of the quantum barrier layer 232a is higher than the Fermi energy level (represented by dotted lines). Thereby, the quantum well 234a closest to the p-type semiconductor layer 240 achieves the quantum confinement effects to a proper extent, the electrons are precluded from overflowing to the p-type semiconductor layer 240, and thus non-radiative recombination of electrons and holes can be prevented, and the resultant reduction of luminous intensity can be also prevented.

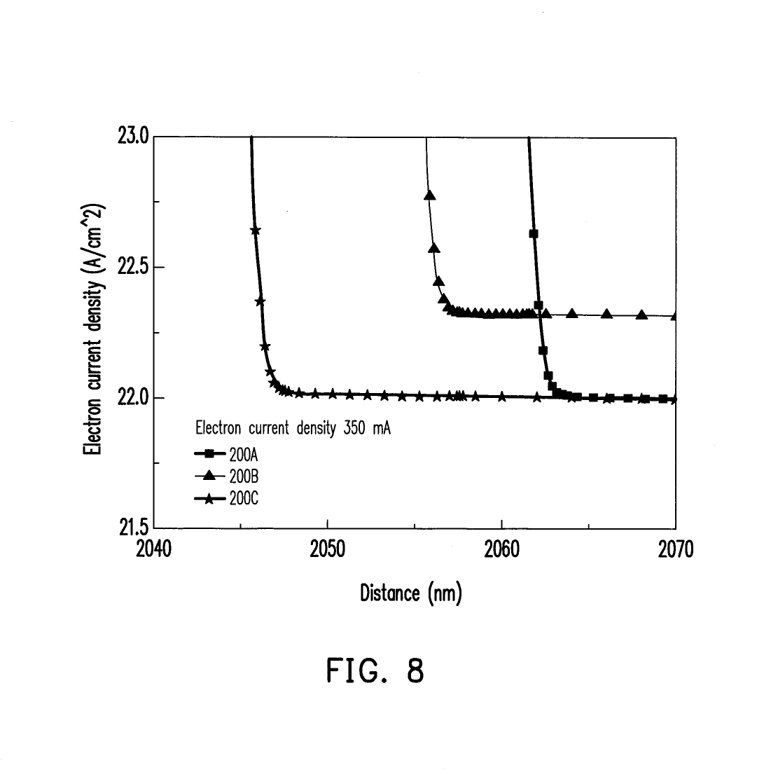

FIG. 8 is a simulation diagram illustrating electron current density of the LEDs respectively depicted in FIG. 4A to FIG. 4C. The definition of the horizontal axis in FIG. 8 is the same as that in FIG. 6A to FIG. 6C, and the vertical axis represents electron current density (unit: A/cm²). With reference to FIG. 8, the electron current density of the p-type semiconductor layer 240 in the LED 200B is greater than that in the LEDs 200A and 200C. This indicates that the LED 200B encounters the issue of electron overflow.

The probability of wave-function overlap in each quantum well 234 is simulated and shown in Table 1.

TABLE 1

| | Quantum | Quantum | Quantum | Quantum | Quantum |
|---|---|---|---|---|---|
| | well | well | well | well | well |
| LED | 234e | 234d | 234c | 234b | 234a |
| 200A | 28.02 | 28.54 | 28.61 | 31.33 | 21.19 |
| 200B | 27.69 | 29.29 | 31.49 | 33.49 | X |
| 200C | 35.56 | 34.54 | 34.69 | 33.53 | 21.77 |

With reference to Table 1 and FIG. 8, the conductive band of the LED 200B is lower than the Fermi energy level, and carriers cannot be confined to the quantum well 234a closest to the p-type semiconductor layer 240, thus excessive electrons overflowing to the p-type semiconductor layer 240. FIG. 4B also evidences that the quantum well 234a closest to the p-type semiconductor layer 240 in the LED 200B has overly high electron concentration. In addition, as indicated in FIG. 8, the electron overflow problem in the LED 200B is relatively serious; therefore, the wave functions of electron-hole pairs cannot be overlapped, nor can the electron-hole pairs be recombined for emitting light.

Based on the above, similar to the thickness variation of the quantum barrier layers in the LED 200B, when the thicknesses of the quantum barrier layers 232 in the LED 200 gradually decrease (if counting from the n-type semiconductor layer 220 to the p-type semiconductor layer 240), the luminous intensity of the LED 200 cannot be effectively improved. In contrast thereto, similar to the thickness variation of the quantum barrier layers in the LED 200C, when the thicknesses of the quantum barrier layers 232 in the LED 200 gradually increase (if counting from the n-type semiconductor layer 220 to the p-type semiconductor layer 240), the electron and hole concentrations in the quantum wells 234 are uniform, and the probability of the wave-function overlap of the electron-hole pairs in the LED 200C is greater than the probability of the wave-function overlap in the LED 200A in which the quantum barrier layers 232a-232f have the same thickness. Hence, compared to the LEDs 200A and 200B, the LED 200C described in the present embodiment has the most favorable luminous intensity.

Among the quantum barrier layers 232 of the active layer 230, the luminous intensity of the LED 200 is basically affected by the thickness variation of the quantum barrier layers 232 close to the p-type semiconductor layer 240. The impact on the luminous intensity at the 222 nm-405 nm wavelength range results from the difference in thicknesses of the quantum barrier layers 232 in the LED 200, which is further explained below.

According to the present embodiment, it is assumed that the active layer 230 of the LED 200 has the structure shown in FIG. 3, and the current of 300 mA and the current of 700 mA are applied. On these conditions, when the thicknesses of the quantum barrier layers 232a-232f (unit: nm) at different locations are changed, the luminous intensity of the LED 200 is provided in Table 2. Herein, the thickness of each of the quantum wells 234a-234e is 3 nm. Besides, in the present embodiment, the quantum wells 234a-234e are made of In_{c}Ga_{1-c}N, for instance, and 0≦c≦0.05; the quantum barrier layers 232a-232f are made of Al_{d}Ga_{1-d}N, for instance, and 0.13≦d≦0.30 (preferably 0.16≦d≦0.25).

Namely, according to the present embodiment, the active layer 230 has six quantum barrier layers 232a-232f, as indicated in FIG. 3. A thickness of each of the six quantum barrier layers 232a-232f, counting from the p-type semiconductor layer 240, is T₁, T₂, T₃ . . . , and Tᵢ in sequence (i=6 in the present embodiment). Namely, T₁ represents the thickness of the quantum barrier layer 232a closest to the p-type semiconductor layer 240, and T₆ represents the thickness of the quantum barrier layer 232f closest to the n-type semiconductor layer 220.

TABLE 2

| | | | | | | | Luminous | Luminous |
|---|---|---|---|---|---|---|---|---|
| | | | | | | | intensity at | intensity at |
| LED | T₆ | T₅ | T₄ | T₃ | T₂ | T₁ | 350 mA | 700 mA |
| I | 9 | 9 | 9 | 9 | 9 | 11 | 17.0 | 36.3 |
| II | 9 | 9 | 9 | 6 | 6 | 6 | 5.9 | 17.3 |
| III | 9 | 9 | 6 | 6 | 9 | 11 | 24.0 | 45.7 |
| IV | 6 | 6 | 6 | 6 | 9 | 11 | 30.3 | 59.0 |
| V | 3 | 3 | 5 | 7 | 9 | 11 | 33.1 | 61.6 |

As shown in Table 2, the LED I has the luminous intensity of 17.0 mW when the current of 350 mA is applied. With reference to FIG. 3 and Table 2, among the three quantum barrier layers 232a-232c close to the p-type semiconductor layer 240 in the LED 200, when the thickness T₁ of the quantum barrier layer 232a closest to the p-type semiconductor layer 240 is greater than the thicknesses T₂ and T₃ of the quantum barrier layers 232b and 232c relatively close to the n-type semiconductor layer 220 (i.e., when T₁ is greater than T₂ and greater than T₃), the luminous intensity of the LED 200 can be effectively improved.

Specifically, compared to the luminous intensity of the LED I, the luminous intensity of the LED II is significantly reduced to 5.9 mW. Since the thickness T₁ of the quantum barrier layer 232a closest to the p-type semiconductor layer 240 in the LED II is relatively small, the electrons may not be effectively confined in the quantum well, and the luminous intensity of the LED II is lessened to a great extent. This complies with the mechanism described in the previous embodiments.

Compared to the thicknesses T₃ and T₄ of the intermediate quantum barrier layers 232c and 232d in the LED I, the thicknesses T₃ and T₄ of the intermediate quantum barrier layers 232c and 232d in the LED III are reduced, and the luminous intensity of the LED III can then be raised to 24 mW. With said thickness design, the holes can be easily injected to the more quantum wells 234a-234e toward the n-type semiconductor layer 220 relative to LED I. In the LED IV, the thicknesses of the quantum barrier layers 232e and 232f are further reduced, and the light output power is drastically raised to 30.3 mW.

In the LED V, the thicknesses T₁-T₆ of the quantum barrier layers 232a-232f gradually decrease if counting from the p-type semiconductor layer 240 to the n-type semiconductor layer 220. As indicated in Table 2, together with the gradual reduction of thicknesses from T₁ to T₆, the luminous intensity is gradually doubled to about 33.1 mW. Namely, the thicknesses T₁-T₃ of the three quantum barrier layers 232 closest to the p-type semiconductor layer 240 in the LED satisfy T₁≧T₂ and T₁≧T₃, such that holes may be evenly distributed into the quantum wells of the active layer, and that electron overflow can be suppressed. Thereby, luminous intensity of the LED can be effectively enhanced.

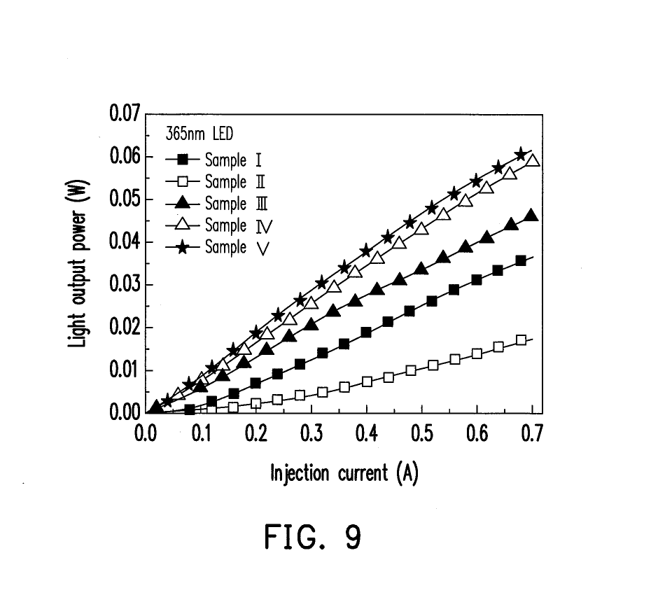

FIG. 9 illustrates light output power-injection current curves of the LEDs provided in Table 2. It can be learned from Table 2 and FIG. 9 that the light output power of the LED can be improved by adjusting the thicknesses of the quantum barrier layers 232a-232f in the active layer 230. Specifically, since the three quantum barrier layers 232a-232c close to the p-type semiconductor layer 240 affect the hole mobility to a greater extent than the other quantum barrier layers 232d-232f, the luminous intensity can be effectively enhanced by adjusting the thicknesses of the quantum barrier layers 232a-232c.

Among the i quantum barrier layers 232 in the active layer 230, if, compared to the thicknesses T₂-Tᵢ, the thickness T₁ has the greatest value, the luminous intensity of the LED can be ameliorated.

According to Table 2, the thicknesses (e.g., T₃ and T₄) of the intermediate quantum barrier layers may be smaller than the thicknesses of the quantum barrier layers close to the n-type semiconductor layer 220 and the p-type semiconductor layer 240 in the LED (e.g., the LED III), and the light output power can be improved in an effective manner. On the other hand, the thicknesses of the quantum barrier layers 232e and 232f close to the n-type semiconductor layer 220 may be designed to be smaller than the thicknesses of the quantum barrier layers 232a and 232b close to the p-type semiconductor layer 240, such that the thicknesses of the quantum barrier layers 232c-232f are equal. As such, the light output power of the LED (e.g., the LED IV) can be further enhanced. Note that the luminous intensity of the LED (e.g., the LED V in which the thicknesses of the quantum barrier layers 232 gradually decrease if counting from the p-type semiconductor layer 240 to the n-type semiconductor layer 220) has the greatest value in comparison with the luminous intensity of the LEDs I˜IV.

According to the experimental results described above, it can be deduced that the light emitting efficiency of the LED can be effectively ameliorated by evenly distributing the electron-hole pairs into the quantum wells of the active layer 230 and by enhancing the carrier confinement effects of the quantum barrier layers close to the p-type semiconductor layer 240.

Taking the six quantum barrier layers 232 described in the above experiments as an example, the thickness T₁ of the first quantum barrier layer 232a closest to the p-type semiconductor layer 240 has the greatest value, and the thickness T₂ of the second quantum barrier layer 232b is smaller than or equal to the thickness T₁ of the first quantum barrier layer 232a. Thereby, the first quantum well closest to the p-type semiconductor layer 240 can achieve the confinement effects to a better extent, electron overflow can be prevented, and radiative recombination of electrons and holes can be accomplished.

In view of the above experiments and inference, the thickness T₁ of the first quantum barrier layer 232a closest to the p-type semiconductor layer 240 has the greatest value; thereby, electron overflow can be prevented, and radiative recombination of electrons and holes can be more efficient. Hence, people skilled in the art should be aware that the first quantum well closest to the p-type semiconductor layer 240 can have favorable confinement effects when the thickness T₂ of the second quantum barrier layer 232b is equal to the thickness T₁ of the first quantum barrier layer 232a. As such, electron overflow can still be prevented, and radiative recombination of electrons and holes can still be accomplished.

To be more specific, compared to the thicknesses T₁ and T₂, the thickness T₃ of the third quantum barrier layer 232c has the least value within the thicknesses T₁ to T₃ (see the LEDs III˜V in Table 2). This is conducive to hole injection, i.e., the holes can be effectively injected into the quantum wells 234 toward the n-type semiconductor layer 220, and the holes can be evenly distributed into the active layer 230. Besides, as shown in Table 2, when T₁>T₂=T₃, the light output power of the LED I can be greater than the LED II. Besides, when the thickness Tᵢ (i=6 in the present embodiment) of the quantum barrier layer closest to the n-type semiconductor layer has the smallest value, the LEDs IV and V shown in Table 2 have favorable luminous intensity, given that the current of 350 mA and the current of 700 mA are applied. That is, when the thickness Tᵢ of the quantum barrier layer closest to the n-type semiconductor layer has the least value among the thicknesses of i quantum barrier layers, the light output power can be effectively enhanced.

The number of the quantum wells and the quantum barrier layers in the active layer is further changed below. Table 3 shows luminous intensity when the layer number of the quantum wells and the quantum barrier layers in the active layer is changed, (six, nine, and eleven quantum barrier layers), the thicknesses (unit: nm) of the quantum barrier layers at different locations are varied, and the current of 300 mA and the current of 700 mA are applied. Here, the thickness of each quantum well is 3 nm. Namely, in the “structure” column, the numbers from right to left represent the thicknesses T₁, T₂, T₃, . . . , and Tᵢ of the quantum barrier layers 232a-232i counting from the p-type semiconductor layer.

TABLE 3

| | Quantum | | Luminous | Luminous |
|---|---|---|---|---|
| | barrier | Structure | intensity | intensity |
| LED | layer | (Tᵢ/ . . . /T₃/T₂/T₁) | at 350 mA | at 700 mA |
| I | 6 | 9/9/9/9/9/11 | 17.0 | 36.3 |
| V | 6 | 3/3/5/7/9/11 | 33.1 | 61.6 |
| VI | 9 | 9/9/9/9/9/9/9/9/11 | 16.4 | 35.5 |
| VII | 9 | 2/3/3/5/5/7/7/9/11 | 24.7 | 46.8 |
| VIII | 11 | 9/9/9/9/9/9/9/9/9/9/11 | 11.3 | 25.4 |
| IX | 11 | 2/2/3/3/3/5/5/7/7/9/11 | 20.7 | 39.2 |

As shown in Table 2 and Table 3, no matter whether the active layer 230 has eight or ten quantum wells 234 (i.e., the active layer 230 has nine or eleven quantum barrier layers 232), the light emitting efficiency of the LED can be effectively improved as long as the thickness of each of the i quantum barrier layers 232 in the active layer 230 satisfies T₁>T₂≧T₃. In particular, provided that the thicknesses of the quantum barrier layers 232 gradually changed, the LED can have favorable light emitting efficiency. For instance, by comparing the LEDs VI and VII having eight quantum wells 234, it can be found that the thicknesses T₈-T₂ of the quantum barrier layers 232 in the LED VI are set to be 9 nm, and the thickness T₁ is set to be 11 nm. After adjusting the thicknesses T₉-T₁ of the quantum barrier layers 232 in the LED VII to be 2/3/3/5/5/7/7/9/11 nm in sequence, the light output power (luminous intensity) of the LED can be effectively raised to 24.7 mW from 16.4 mW.

On the other hand, by comparing the LEDs VIII and IX having ten quantum wells 234, it can be found that the thicknesses T₁₁-T₂ of the quantum barrier layers 232 in the LED VIII are set to be 9 nm, and the thickness T₁ is set to be 11 nm. After adjusting the thicknesses T₁₁-T₁ of the quantum barrier layers 232 in the LED IX to be 2/2/3/3/3/5/5/7/7/9/11 nm in sequence, the light output power (luminous intensity) of the LED can be effectively raised to 20.7 mW from 11.3 mW.

The effect of defect density in an active region on carriers can be lowered by intentionally doping n-type dopants through adjusting the layer number and the doping concentrations of the doped quantum barrier layers 232, thereby enhancing the luminous efficiency. Particularly, the enhancement effect is especially pronounced for the light that is emitted from the active layer 230 and has a wavelength range from 222 nm to 405 nm.

When a layer number k of the doped quantum barrier layers and a total number i of the quantum barrier layers 232 satisfy the following formula, the enhancement effect of the luminous efficiency is especially pronounced: when i is an even number, k≧i/2; when i is an odd number, k≧(i−1)/2. Namely, in the quantum barrier layers 232 of the LED, if the layer number of the doped quantum barrier layers exceeds half the total number of the quantum barrier layers 232, and the dopant concentration in the doped quantum barrier layers is from about 5×10¹⁷/cm³ to about 1×10¹⁹/cm³, the light emitting efficiency of the LED can be effectively raised.

In light of the foregoing, the thicknesses of the quantum barrier layers of the active layer in the LED satisfy a certain relationship. Thereby, holes can be evenly distributed into the quantum wells, and the recombination of the carriers in the LED can be more efficient. As a result, by employing any one of the afore-described techniques, the luminous intensity of the LED at the 222 nm-405 nm wavelength range in the disclosure can be significantly improved.

Moreover, the LED of the disclosure is not limited to the embodiments depicted above. The LED may be configured with horizontal electrodes or vertical electrodes, both of which can implement the disclosure but should not be construed as limiting the disclosure.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A light emitting diode comprising:
a substrate;
an n-type semiconductor layer and a p-type semiconductor layer, wherein the n-type semiconductor layer is located between the substrate and the p-type semiconductor layer;
an active layer located between the n-type semiconductor layer and the p-type semiconductor layer, wherein a wavelength of light emitted by the active layer is λ, 222 nm≦λ≦405 nm, the active layer includes i quantum barrier layers and (i−1) quantum wells, each of the quantum wells is located between any two of the quantum barrier layers, i is a natural number greater than or equal to 2, a thickness of each of the quantum barrier layers, counting from the p-type semiconductor layer, is T₁, T₂, T₃ . . . , and Tᵢ in sequence, and T₁ is greater than T₂ and T₃; and
a first electrode and a second electrode, wherein the first electrode is located on a portion of the n-type semiconductor layer, and the second electrode is located on a portion of the p-type semiconductor layer.

2. The light emitting diode as recited in claim 1, wherein T₂≧T₃.

3. The light emitting diode as recited in claim 1, wherein an i^{th} quantum barrier layer of the i quantum barrier layers closest to the n-type semiconductor layer has the smallest thickness Tᵢ.

4. The light emitting diode as recited in claim 1, wherein an n-type dopant is doped into at least k quantum barrier layers of the i quantum barrier layers, k is a natural number greater than or equal to 1, k≧i/2 when i is an even number, and k≧(i−1)/2 when i is an odd number.

5. The light emitting diode as recited in claim 4, wherein a dopant concentration in the k quantum barrier layers is from 5×10¹⁷/cm³ to 1×10¹⁹/cm³.

6. The light emitting diode as recited in claim 1, wherein a first quantum barrier layer of the i quantum barrier layers closest to the p-type semiconductor layer has the thickness T₁ ranging from 6 nm to 15 nm.

7. The light emitting diode as recited in claim 1, wherein a material of the quantum barrier layers comprises AlₓIn_{y}Ga_{1-x-y}N, 0≦x≦1, 0≦y≦0.3, and x+y≦1.

8. The light emitting diode as recited in claim 1, wherein a material of the quantum wells comprises AlₘInₙGa₁₋ₘ₋ₙN, 0≦m≦1, 0≦n≦0.5, m+n≦1, x>m, and n≧y.

9. A light emitting diode comprising:
a substrate;
an n-type semiconductor layer and a p-type semiconductor layer, wherein the n-type semiconductor layer is located between the substrate and the p-type semiconductor layer;
an active layer located between the n-type semiconductor layer and the p-type semiconductor layer, wherein a wavelength of light emitted by the active layer is λ, 222 nm≦λ≦405 nm, the active layer includes i quantum barrier layers and (i−1) quantum wells, each of the quantum wells is located between any two of the quantum barrier layers, i is a natural number greater than or equal to 2, a thickness of each of the quantum barrier layers, counting from the p-type semiconductor layer, is T₁, T₂, T₃ . . . , and Tᵢ in sequence, and T₁=T₂>T₃; and
a first electrode and a second electrode, wherein the first electrode is located on a portion of the n-type semiconductor layer, and the second electrode is located on a portion of the p-type semiconductor layer.

10. The light emitting diode as recited in claim 9, wherein an i^{th} quantum barrier layer of the i quantum barrier layers closest to the n-type semiconductor layer has the smallest thickness Tᵢ.

11. The light emitting diode as recited in claim 9, wherein an n-type dopant is doped into at least k quantum barrier layers of the i quantum barrier layers, k is a natural number greater than or equal to 1, k≧i/2 when i is an even number, and k≧(i−1)/2 when i is an odd number.

12. The light emitting diode as recited in claim 11, wherein a dopant concentration in the k quantum barrier layers is from 5×10¹⁷/cm³ to 1×10¹⁹/cm³.

13. The light emitting diode as recited in claim 9, wherein a first quantum barrier layer of the i quantum barrier layers closest to the p-type semiconductor layer has the thickness T₁ ranging from about 6 nm to about 15 nm.

14. The light emitting diode as recited in claim 9, wherein a material of the quantum barrier layers comprises AlₓIn_{y}Ga_{1-x-y}N, 0≦x≦1, 0≦y≦0.3, and x+y≦1.

15. The light emitting diode as recited in claim 9, wherein a material of the quantum wells comprises AlₘInₙGa₁₋ₘ₋ₙN, 0≦m≦1, 0≦n≦0.5, m+n≦1, x>m, and n≧y.
